(19) United States
(12) Patent Application Publication
(10) Pub. No.: US 2025/0391698 A1
(43) Pub. Date: Dec. 25, 2025

(54) CHIPS DIRECT BONDING METHOD

(71) Applicant: Commissariat à I'Énergie Atomique et aux Énergies Alternatives, Paris (FR)

(72) Inventors: Pierre Montmeat, Grenoble (FR); Franck Fournel, Grenoble (FR); Mélanie Vacon, Grenoble (FR)

(73) Assignee: Commissariat à I'Énergie Atomique et aux Énergies Alternatives, Paris (FR)

(21) Appl. No.: 19/241,847

(22) Filed: Jun. 18, 2025

(30) Foreign Application Priority Data
Jun. 19, 2024 (FR) FR2406560

(51) Int. Cl. H01L 21/683; H01L 21/306; H01L 21/3065; H01L 21/78; H01L 23/00

(52) U.S. Cl. CPC H01L 21/6836; H01L 21/30625; H01L 21/3065; H01L 21/78; H01L 24/80; H01L 2221/68327; H01L 2221/6834; H01L 2221/68354; H01L 2221/68368; H01L 2221/6839; H01L 2224/80895; H01L 2224/80896

(57) ABSTRACT

A method for bonding chips including the following steps: a) providing a donor substrate wherein chips are formed, the donor substrate including a front face and a back face, b) mounting the front face of the donor substrate to a temporary substrate, by direct bonding, c) preferably thinning the donor substrate, d) bonding the assembly consisting of donor substrate and temporary substrate on a handling device including a solid frame and an adhesive film, with the back face of the donor substrate bonded to the adhesive film, e) separating the temporary substrate from the donor substrate, f) cutting the donor substrate so as to singularize the chips, g) bonding the chips to the receiver substrate by direct bonding.

### CROSS REFERENCE TO RELATED APPLICATIONS

This application claims priority to French application number 2406560, filed Jun. 19, 2024. The contents of which is incorporated by reference in its entirety.

### TECHNICAL FIELD

The present disclosure generally relates to the field of microelectronics, and more particularly to electronic chip bonding methods.

### BACKGROUND ART

In microelectronics, direct bonding is used to assemble components that have been prepared individually on various supports. For example, chips can be manufactured on a donor substrate and then bonded to a receiver substrate.

Direct bonding is spontaneous bonding without the use of liquid adhesive material. It is generally performed at room temperature, although hot surfaces can also be bonded. It is generally performed at ambient pressure, but can also be performed under vacuum. As it's a spontaneous bond, there's no need to exert force on the two surfaces to be bonded. However, light local pressure can be used to initiate bonding from a specific point. The bonding then propagates itself along the surfaces with a bonding wave.

Typically, a direct chip bonding method comprises the following steps (FIG. 1, views A) to D)):
bonding a donor substrate 10, in which chips 15 are formed, to a handling device 20 comprising a solid frame 21 and an adhesive tape 22, the back face 12 of the substrate 10 being bonded to the adhesive tape 22, the front face 11 of the donor substrate 10 being accessible (FIG. 1, view A)),
cutting the donor substrate 10 between the chips 15 to singularize them (FIG. 1, view B)),
cleaning the front face 11 of chips 15 (FIG. 1, view C)),
bonding the front face 11 of chips 15 to a receiving substrate 30 (FIG. 1, view D)).

The step for cleaning the front face of the chips is essential, since direct bonding is very demanding in terms of the cleanliness of the surface to be bonded. It must be as clean as possible of organic and particulate contamination. For example, it can be cleaned using a combination of plasmas and aqueous solutions, which could or could not be combined with sound waves. The chips can then be released after the adhesive tape has been insolated with UV light. Such a method is, for example, described in the work of Sanchez et al. (“Chip to wafer direct bonding technologies for high density 3D integration”, 2012, IEEE 62nd Electronic Components and Technology Conference, 1960-1964 and “Collective Die Direct Bonding for Photonic on Silicon”, 2018, ECS Trans., 86, 5, 223).

The silicon substrates from which chips are formed are generally between 500 and 700 μm thick. However, for certain applications, it is necessary to bond very thin chips (typically less than 200 μm thick). It is therefore necessary to thin the substrate. Thinning of the donor substrate can be achieved by abrasion (or lapping) using diamond wheels. While this technique enables very uniform thicknesses to be achieved, it also increases the roughness of the front face of the substrate. For a silicon substrate, the roughness RMS of the front face can exceed 100 nm, which is not compatible with direct bonding, where the roughness must be less than 0.5 nm. Nor is it possible to flatten the front face easily, as the configuration of a wafer bonded to adhesive tape is not compatible with chemical-mechanical polishing.

In addition, at such thicknesses, the thin wafer is no longer solid enough to be handled without care.

One solution would be to use a transfer step to thin the back face of the donor substrate according to the following steps (FIG. 2, views A) to G)):
bonding a donor substrate 10, in which chips 15 are formed, to a first handling device 20 comprising a solid frame 21 and adhesive tape 22, with the front face 11 of the donor substrate 10 bonded to the adhesive tape and the back face 12 of the donor substrate 10 accessible (FIG. 2, view A)),
thinning the back face 12 of donor substrate 10 (FIG. 2, view B),
bonding the donor substrate 10 to a second handling device 23 comprising a solid frame 24 and an adhesive tape 25, with the back face 12 of the donor substrate 10 bonded to the adhesive tape 25 (FIG. 2, view C)),
separating the donor substrate 10 from the first handling device 20, for example by insolating the adhesive tape 22 (FIG. 2, view D),
cutting the donor substrate 10 to singularize the chips 15 (FIG. 2, view E)),
cleaning the front face 11 of chips 15 (FIG. 2, view F)),
bonding the front face 11 of the chips to a receiving substrate 30 (FIG. 2, view G)).

However, the front face 11 of the chips 15 has been in contact with the glue of the adhesive tape 22 of the first handling device, making it very difficult to clean. The poor surface quality leads to numerous bonding defects. Such a method is even more problematic for hybrid direct bonding with a surface comprising copper and silicon oxide, as the copper is exposed from the beginning of the method.

### SUMMARY OF INVENTION

There is a need for a chip bonding method, with little or no defects, as the method must be able to be implemented for thin chips (typically for thicknesses of less than 300 μm, or even less than 100 μm or 50 μm).

This aim is achieved by a method for bonding chips to a receiver substrate comprising the following steps:
a) providing a donor substrate in which chips are formed, the donor substrate comprising a first surface on front face and a second surface on back face,
b) mounting the first surface of the donor substrate to a temporary substrate, by direct bonding,
c) preferably thinning the donor substrate from the second surface,
d) bonding the assembly consisting of the donor substrate and the temporary substrate to a handling device comprising a solid support and an adhesive film, with the second surface of the donor substrate bonded to the adhesive film,
e) separating the temporary substrate from the donor substrate,
f) cutting the donor substrate so as to individualize the chips,
g) bonding the chips to the receiver substrate by direct bonding.

According to one specific embodiment, step f) is performed between step b) and step d).

According to one specific embodiment, in step b), the first surface of the donor substrate is coated by a protective layer.

According to one specific embodiment, the protective layer is an amorphous carbon layer, a silicon layer, or a polymer layer, for example a layer of acrylate or one of its derivatives.

According to one specific embodiment, the first surface of the donor substrate is a surface comprising silicon oxide and copper.

According to one specific embodiment, the first surface of the donor substrate is made of silicon, germanium, a III/V material such as AsGa or InP, or a II/VI material such as CdHgTe.

According to one specific embodiment, a step for trimming the donor substrate is performed either before step b) or after step b).

According to one specific embodiment, the chips have a surface area of between 0.5×0.5 mm² and 20×20 mm².

According to one specific embodiment, the chips have a thickness of less than 300 μm, preferably less than 100 μm, even more preferably less than 50 μm.

According to one specific embodiment, step f) is performed by plasma etching.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1 views A), B), C), D), previously described, schematically illustrates various steps in a chip bonding method according to the prior art;

FIG. 2 views A), B), C), D), E), F), G), previously described, schematically illustrates various steps in another chip bonding method according to the prior art;

FIG. 3A, FIG. 3B, FIG. 3C, FIG. 3D, FIG. 3E, FIG. 3F, FIG. 3G, and FIG. 3H schematically illustrate various steps in a chip bonding method according to one specific embodiment of the invention;

FIG. 4A, FIG. 4B, FIG. 4C, FIG. 4D, FIG. 4E, FIG. 4F, FIG. 4G, and FIG. 4H schematically illustrate various steps in a chip bonding method according to another particular embodiment of the invention; and

FIG. 5A, FIG. 5B, FIG. 5C, FIG. 5D, FIG. 5E, FIG. 5F, FIG. 5G, and FIG. 5H schematically illustrate various steps in a chip bonding method according to another particular embodiment of the invention.

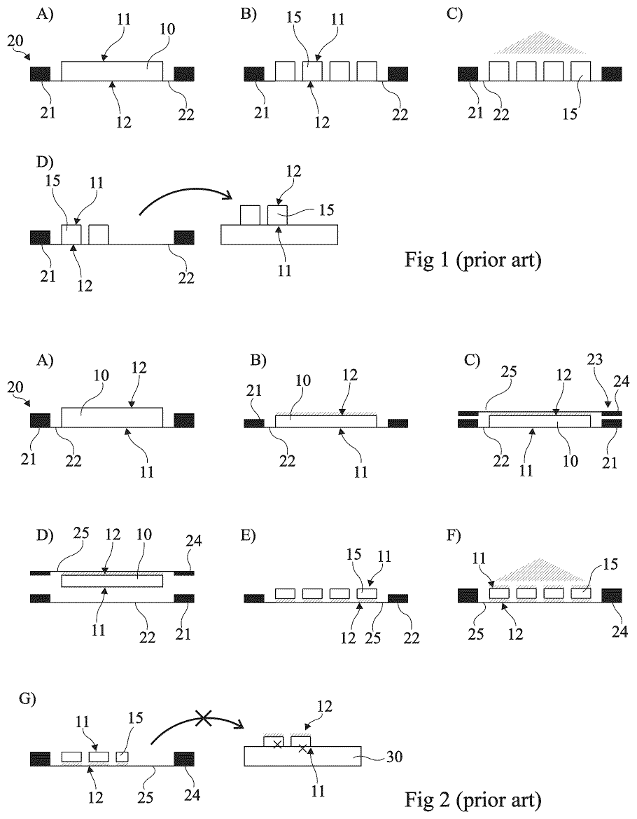

### DESCRIPTION OF EMBODIMENTS

Like features have been designated by like references in the various figures. In particular, the structural and/or functional features that are common among the various embodiments could have the same references and could dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

Between X and Y means that X and Y are included.

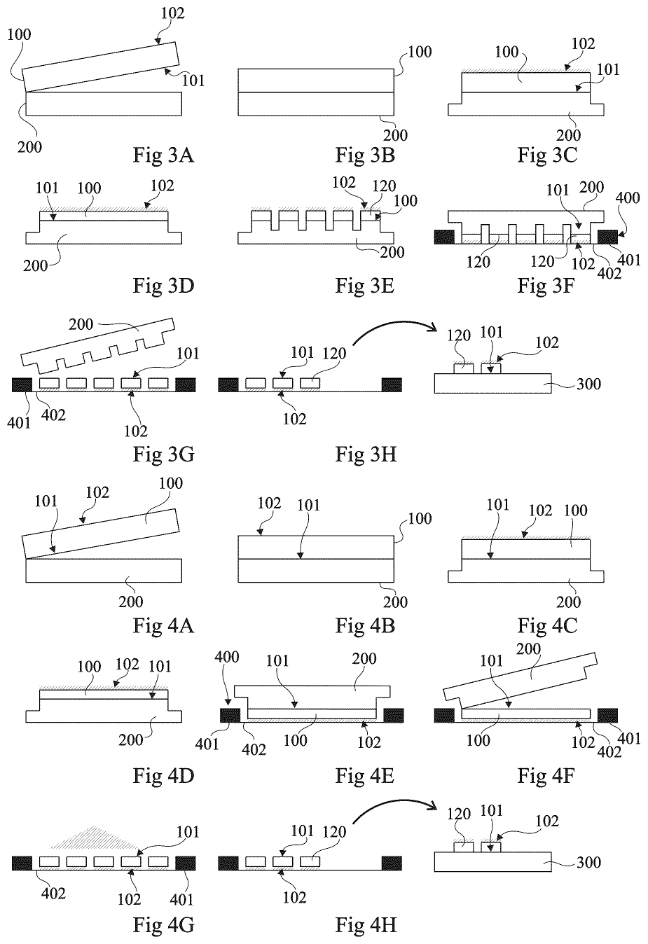

We will now describe the chip bonding method in more detail with reference to the attached FIGS. 3A to 3H, 4A to 4H, and 5A to 5H.

The method comprises the following steps:
a) providing a donor substrate 100 in which chips are formed, the donor substrate 100 comprising a first surface 101 on front face and a second surface 102 on back face (FIGS. 3A, 4A, 5A),
b) mounting the first surface 101 of the donor substrate 100 to a temporary substrate 200, by direct bonding (FIGS. 3B, 4B, 5B),
c) preferably thinning the donor substrate 100 from the second surface (FIGS. 3D, 4D, 5D),
d) bonding the assembly consisting of donor substrate 100 and temporary substrate 200 to a handling device 400 comprising a solid support 401 and an adhesive film 402, the second surface 102 of donor substrate 100 being bonded to adhesive film 402 (FIGS. 3F, 4E, 5E),
e) separating the temporary substrate 200 from the donor substrate 100 (FIGS. 3G, 4F, 5F),
f) cutting the donor substrate 100 so as to singularize the chips 120 (FIGS. 3E, 4G, 5G),
g) bonding the chips 120 to the receiver substrate 300 by direct bonding (FIGS. 3H, 4H, 5H).

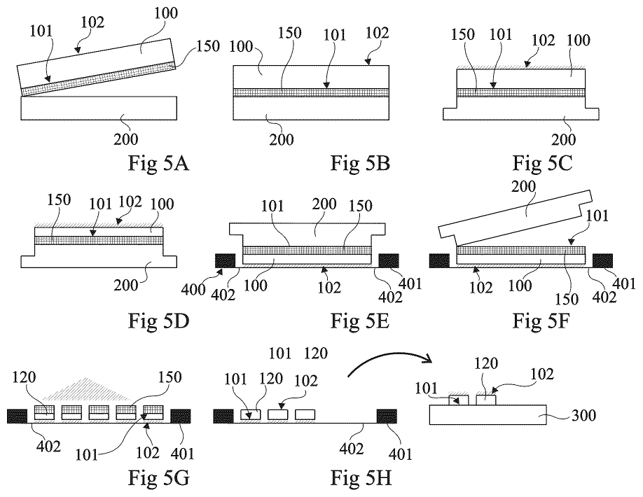

According to a first embodiment, the various steps can be performed in the order a), b), c), d), e), f), and g) as shown, for example, in FIGS. 4A to 4H and FIGS. 5A to 5H.

According to a second embodiment, the various steps can be performed in the order a), b), c), f), d) e), and f) as shown, for example, in FIGS. 3A to 3H.

Performing a direct bonding to mount the donor substrate 100 to the temporary substrate 200 allows the surface 101 of the donor substrate 100 on front face to be protected, and therefore the chips 102, during the thinning and/or cutting steps. Once the chips 120 have been thinned, cut, and separated from the temporary substrate 200, they can be bonded to the receiver substrate 300 by a further direct bonding. In such a method, the chips 120 and the front face of the donor substrate 100 are not in contact with the adhesive film 402. As the front surface 101 of the chips is clean and not very rough, the resulting bonding has few or no defects.

Prior to step a), one or more pre-processes can be performed on the donor substrate 100 and/or the temporary substrate 200 so as to make them compatible with direct bonding.

Pre-process can be selected from the following pre-processes: thermal annealing, plasma, polishing, and wet cleaning.

By way of example, it is possible to form an oxide layer on the surface of the temporary substrate 200 and/or to perform a polishing step on the temporary substrate 200 and/or on the donor substrate 100 to obtain a roughness compatible with direct bonding (typically a roughness of less than 0.5 nm RMS). It is possible to implement methods that combine, for example, a plasma and an aqueous solution, in particular oxygen plasma followed by wet cleaning using CARO (mixture of H₂SO₄, H₂O₂) combined with SC1 (mixture of H₂O, NH₃, H₂O₂). It is also possible to make the surface of the temporary substrate 200 hydrophobic with an HF-based solution if the substrate 200 is made of silicon, for example.

The donor substrate 100, supplied in step a), comprises a first surface 101 (or first main surface) on front face and a second surface 102 (or second main surface) on back face. The first surface 101 and the second surface 102 are parallel to each other. The first surface 101 on front face corresponds to the surface to be prepared for direct bonding to the receiver substrate 300.

At the time of step a), chips 120 have already been formed in the donor substrate 100. The chips 120 are positioned on front face of the donor substrate 100. After singularization, the chips will have a thickness of between a few microns and the total thickness of the wafers (without thinning). The chips have a surface area, for example, of between 0.5×0.5 mm² and 20×20 mm².

The donor substrate 100 is, for example, a wafer. The wafer can have a diameter of between 25 mm and 300 mm, preferably between 100 mm and 300 mm.

The donor substrate 100 can be a solid substrate 110 made of semiconductor material.

The donor substrate 100 is, for example, made of silicon, germanium, a III/V material such as AsGa, InP or a II/VI material such as CdHgTe.

The donor substrate 100 could comprise a support substrate coated, on front face, by a thin dielectric layer, in particular an oxide layer (silicon oxide in particular). The thin oxide layer can be formed, for example, by deposition.

The donor substrate 100 could be a SOI (‘Silicon on Insulator’) substrate, i.e. a substrate comprising a carrier substrate coated successively by a thin layer of buried oxide and a layer of silicon. It can also be a BSOI (‘Bonded Silicon On Insulator’) substrate comprising a silicon film and a silicon oxide layer.

The first surface of the donor substrate 100 can be a semiconductor material surface or an oxide surface, for example a silicon oxide surface.

According to one specific embodiment, the first surface 101 of the donor substrate 100 can be a hybrid surface, formed of several materials (at least two materials). Preferably, it is a Cu/SiO₂ hybrid layer comprising a silicon oxide matrix in which copper portions (pads) have been formed. The copper pads are, for example, 2 μm square. Such pads can be formed using a Damascene method.

The first surface 101 of the donor substrate 100 can be a surface on which microelectronic devices such as CMOS (‘Complementary metal-oxide-semiconductor’), interconnection levels, and hybrid bonding levels have been formed.

As shown in FIGS. 5A to 5H, the first surface 101 of the donor substrate 100 can be coated by a protective layer 150.

According to one preferred embodiment, the protective layer 150 can be bonded to the donor substrate 100 by direct bonding. This allows close contact between the protective layer 150 and the donor substrate 100 to be provided.

This embodiment can be performed according to the following steps:
i) bonding to the donor substrate 100, a transfer substrate comprising a support and the protective layer 150,
ii) removing the support from the transfer substrate, so as to form an assembly comprising the donor substrate 100 coated by the protective layer 150.

According to another embodiment, the protective layer 150 can be deposited on the donor substrate 100.

The polymer layer can have a thickness of between 20 and 50 nm.

The protective layer 150 can be a silicon layer, an amorphous carbon layer, or a polymer layer, for example.

The polymer is, for example, an acrylate or a derivative thereof, e.g. an acrylate with adamantane groups, in particular BARC. The polymer layer can be 32 nm thick, for example.

The temporary substrate 200 (or substrate handle) can be made of a solid substrate. For example, it can be a wafer with a diameter of between 25 and 300 mm, preferably between 100 mm and 300 mm. The temporary substrate 200 must be the same size as the donor substrate 100.

The temporary substrate 200 is, for example, made of silicon, germanium, a III/V material such as AsGa, InP or a II/VI material such as CdHgTe.

The temporary substrate 200 could comprise a carrier substrate coated by a thin dielectric layer. In particular, the thin layer is an oxide layer, for example a silicon oxide layer.

The temporary substrate 200 can be an SOI substrate.

In step b), the donor substrate 100 and the temporary substrate 200 are brought into contact to be mounted by direct bonding.

Hydrophobic bonding can be perfpormed, for example, by using a donor substrate 100 the first surface 101 of which is made of silicon and a temporary substrate 200 the surface of which to be bonded is made of silicon.

Alternatively, hydrophobic-hydrophilic bonding can be performed with a substrate 200 made of silicon passivated by hydrogen bonds and a substrate 100 the surface 101 of which is a bare copper hybrid surface. With a hydrophobic surface involved in the bonding, the amount of water is limited, which is particularly interesting for sensitive surfaces such as hybrid surfaces with bare copper.

Hydrophilic bonding can also be performed, for example, with two oxide surfaces, in particular silicon oxide. The substrates 100, 200 to be bonded comprise, for example, a silicon support substrate coated by a thin layer of oxide on front face.

For example, a donor substrate 100 can be selected the front surface 101 of which is a hybrid surface, in particular a surface comprising copper pads in an SiO₂ matrix, and a temporary substrate 200 with a silicon surface, for example an SOI-type substrate.

Direct bonding can be performed at atmospheric pressure (i.e. 1013.25 hPa) or under a vacuum.

The assembly does not necessarily need to be consolidated by heat process. However, annealing, at a temperature preferably below 200° C., can be advantageously performed.

The annealing step enhances adhesion. This adhesion is preferably less than 1 J/m², so as to ensure that the temporary substrate 200 can be dismantled at the end of the method. Adhesion can be assessed, for example, by the Maszara method (J. Appl. Phys. 64, 1988, 10).

In the case of hydrophilic direct bonding involving a silicon oxide surface, the annealing temperature is preferably below 150° C.

A step for trimming the donor substrate 100 can be performed before or after the bonding step (step b), for example between steps b) and c) or after c) (FIGS. 3C, 4C, 5C).

The trimming step can be performed, for example, by photolithography/etching, or by mechanical trimming using a diamond saw. The trimming width is, for example, between 1 and 5 mm. The trimming depth will be selected according to the final thickness of the donor substrate 100. Trimming allows the fragility of thinned wafer edges during thinning to be eliminated.

A thinning step is advantageously performed (step c). Thinning is performed from the back face of the donor substrate 100 down to the desired thickness, for example, by abrasion/erosion and/or chemical etching and/or chemical mechanical polishing (CMP).

The thinning step can be performed in several sub-steps. It is possible to combine a mechanical abrasion method with chemical etching methods. In this case, the donor substrate 100 could comprise an etch stop layer. The donor substrate 100 can be thinned up to a thickness in the micrometer range. As the donor substrate 100 is perfectly held by direct bonding to the temporary substrate 200, it can be handled naturally by all microelectronics machines.

After the thinning step, cleaning steps can be performed to limit particulate contamination, particularly with a view to final disassembly. Advantageously, this cleaning can be performed using conventional microelectronics machines, which facilitates and optimizes this step.

Depending on the desired chip thickness 120, the thinning step could not be performed.

In step d), the assembly consisting of donor substrate 100 and temporary substrate 200 is bonded to a handling device 400 comprising a solid frame 401 and an adhesive film 402. The second surface 102 of the donor substrate 100 is bonded to the adhesive tape 402 (in other words, the back of the donor substrate 100 is bonded).

In the highly advantageous case where the chips 120 are cut before separating the temporary substrate 200 from the donor substrate 100 (in other words, in the case where step f) is performed before step d), as shown in FIGS. 3A to 3H), the assembly formed by the cut donor substrate 100 and the temporary substrate is bounded to the handling device 400.

The adhesion between the donor substrate 100 (cut or uncut) and the adhesive tape 102 is very strong (typically over 20 J/m²). The adhesion between the donor substrate 100 and the adhesive tape 102 is thus greater than the adhesion between the temporary substrate 200 and the donor substrate 100 (less than 1 J/m²).

In step e), the donor substrate 100 can be mechanically lifted from the temporary substrate 200 off. Thus, is obtained a surface being directly compatible with direct bonding (‘ready to bond’). Mechanical disassembly can be performed using a blade or wedge. By inserting a wedge/small blade between the temporary substrate 200 and the donor substrate 100, the weakest interface is dismantled, i.e. the interface between the temporary substrate 100 and the donor substrate 200.

It is possible to use automatic dismantling machines that are well known for their temporary bonding technologies. For example, machines from EVG company using a ring to encircle and lift the temporary substrate. A small blade/corner can be used to initiate lift-off. For example, machines from Tazmo company also use a blade to initiate lift-off. The back face of the temporary substrate 200 is clamped by vacuum on a vacuum table, and the surface deformed to propagate the lift-off.

After disassembly, are obtained chips 120 that are already singularized and the first surface 101 of which on front face is directly compatible with direct bonding.

In step f), the chips 120 are separated from each other using a cutting/etching method. This step can be performed using a diamond saw, a laser, stealth dicing or plasma etching, for example (in particular using the Bosch method). Plasma etching can be performed in a standard deep etching machine, as the chips to be singularized are held in place by the temporary substrate 200 or by the adhesive film 402. In addition, plasma etching allows the temporary substrate 200 to be preserved if it is still bonded to the donor substrate 100 when this step is performed. As the chips 120 are not held in place by a metal frame, there is advantageously no need for a dedicated plasma etching machine. It is also possible to use a nanosecond or even better picosecond ablation laser.

As shown in FIGS. 4A to 4H and 5A to 5H, the chips 120 can be cut after separation of the temporary substrate 200 from the donor substrate 100.

If the front face of the chips is not protected during the cutting step (FIGS. 4A to 4H), it could be contaminated by particles from the cutting step. Thus, is performed a cleaning of the chips before step g).

As previously mentioned, a protective layer 150 can be deposited on the donor substrate 100. After step f), the protective layer 150 is removed before final bonding of the chips 120 to the receiver substrate 300 (FIG. 5G). Alternatively, the protective layer 150 can be removed before step f).

The protective layer 150 can be removed, for example, by UV-ozone process or by means of a solution, in particular a tetramethylammonium hydroxide (TMAH) solution.

In step g), the cut, possibly thinned and/or possibly cleaned chips can be bonded to the receiver substrate 300.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

### ILLUSTRATIVE AND NON-LIMITING EXAMPLES

In the following examples 1 to 6, 200 mm diameter silicon wafers are used. Example 7 uses wafers with a diameter of 100 mm.

### Example 1

On a 725 μm silicon wafer, a 500 nm thick silicon oxide deposit is performed. This wafer undergoes a chemical-mechanical polishing method so as to make it compatible with a hydrophilic direct bonding method. Thus, a donor substrate 100 ready for bonding is obtained.

A second 725 μm-thick silicon wafer is cleaned so as to make it compatible with a hydrophilic direct bonding method. A temporary substrate 200 ready for bonding is thus obtained.

Substrates 100 and 200 are assembled by direct bonding. The donor substrate 100 is thinned up to obtain a thickness of 300 μm by mechanical abrasion using a diamond wheel. The donor substrate 100 is then cut with a diamond saw to form 10×10 m² chips. The depth of the cut is 310 μm to ensure complete cutting of the donor substrate 100. The cut penetrates the temporary substrate 200 to a shallow depth (10 μm).

The resulting structure is then attached to a solid frame using Furukawa SP5207M-425 adhesive tape. The thinned face of the donor substrate 100 is bonded to the tape. Inserting a wedge into the bonding separates the handle 200 from the donor substrate 100. 10×10 mm² silicon chips 120 with a thickness of 300 μm are obtained, which are compatible with a direct bonding method.

### Example 2

The donor substrate 100 is a 725 μm silicon wafer, on which a 500 nm thick silicon oxide deposit is performed. This wafer undergoes a chemical-mechanical polishing method so as to make it compatible with a direct bonding method.

The temporary substrate 200 is a second 725 μm-thick silicon wafer, cleaned so as to make it compatible with a hydrophilic direct bonding method.

The donor substrate 100 and the temporary substrate 200 are assembled by direct bonding. This assembly is annealed for 2 hours at 150° C. The donor substrate 100 is then thinned up to a thickness of 200 μm by mechanical abrasion using a diamond wheel. On the thinned donor substrate 100 a trimming is performed using a diamond saw to a width of 1.5 mm and a depth of 220 μm. The donor substrate 100 is then thinned by abrasion to a thickness of 50 μm. Particulate cleaning is then performed using a Megpie® from Prosys company and a diluted 1% ammonia solution.

This structure is then attached to a solid frame using Furukawa SP5207M-425 adhesive tape. The thinned face of the donor substrate 100 is bonded to the tape. By inserting a wedge into the bonding, the handle 200 is dismantled. 5×5 mm² chips are cut from the donor substrate 100 using a diamond saw. 5×5 mm² chips with a thickness of 50 μm are obtained, which are compatible with a hydrophilic direct bonding method after ozone cleaning and Megpie using a 1% ammonia solution.

### Example 3

On a 725 μm silicon BSOI substrate consisting of a 50 μm silicon film and a 400 nm silicon oxide layer, oxidation is performed to form a 50 nm silicon oxide film. The result is a donor substrate 100.

A second 725 μm-thick silicon wafer undergoes an oxidation so as to form a 100 nm silicon oxide film on the surface. A temporary substrate 200 is thus obtained. Substrates 100 and 200 are cleaned to make them compatible with a hydrophilic direct bonding method.

Substrates 100 and 200 are assembled by direct bonding. This assembly is annealed for 2 hours at 150° C. The donor substrate 100 is then thinned up to 200 μm by mechanical abrasion using a diamond wheel. On the thinned donor substrate 100 a trimming is performed to a width of 1.5 mm and a depth of 220 μm using a diamond saw. The donor substrate 100 is then thinned by abrasion to a thickness of 100 μm. The remaining silicon is then etched with an aqueous HF/HNO₃ solution, comprising a 10% HF solution and a 70% HNO₃ solution. Etching stops at the 400 nm silicon oxide layer, consuming it slightly. This oxide layer can be completely removed with HF. On the donor substrate 100, 1×12 mm² chips are cut with a diamond saw. The depth of the cut is 60 μm so as to ensure complete cutting of the donor substrate 100. The cut penetrates the temporary substrate 200 to a depth reduced to 10 μm.

This structure is attached to a solid frame using Furukawa SP5207M-425 adhesive tape. The thinned face of the donor substrate 100 is bonded to the tape. By inserting a wedge into the bonding, the handle 200 is dismantled. 1×12 mm² silicon chips with a thickness of 50 μm are obtained, which are compatible with a hydrophilic direct bonding method after ozone cleaning and Megpie using a 1% ammonia solution.

### Example 4

On a silicon wafer, a damascene method is performed to produce 2 μm copper pads in a SiO₂ matrix. This wafer undergoes a trimming to a width of 1.5 mm and a depth of 220 μm using a diamond saw. A cleaning and then mechanical and chemical polishing is then performed on the donor substrate 100 so as to make it compatible with a hydrophilic direct bonding method.

On a temporary substrate 200, 1 μm SiO₂ is deposited by chemical vapor deposition. The temporary substrate 200 is mechanically and chemically polished. The donor substrate 100 and temporary substrate 200 are assembled by direct bonding. The donor substrate 100 is thinned to 200 μm by mechanical abrasion. On the donor substrate 100, 3×3 mm² chips are cut with a diamond saw. The depth of the cut is 210 μm so as to ensure complete cutting of the donor substrate 100. The cut penetrates the temporary substrate 200 to a depth reduced to 10 μm.

This structure is attached to a solid frame using Adwill D-650 adhesive tape. The thinned face of the donor substrate 100 is bonded to the tape. By inserting a wedge into the bonding, the handle 200 is dismantled. 3×3 mm² silicon chips are obtained, with a 200 μm thickness, the surface of which consists in copper 2-μm-side pads. This surface is compatible with a hydrophilic direct bonding method. An ozone-based cleaning and a Megpie using a solution of EKC PCMP 5650 diluted 1:20 in DI water can be added.

### Example 5

On a 725 μm silicon BSOI substrate (donor substrate 100) consisting of a 50 μm silicon film and a 400 nm silicon oxide layer. 2 μm copper pads are performed in a SiO₂ matrix by a damascene method.

A second 725-μm-thick silicon wafer (temporary substrate 200) undergoes a HF-based cleaning so as to have a hydrophobic surface passivated by Si—H hydrogen bonds.

The substrates 100, 200 are assembled by direct bonding. The donor substrate 100 is then thinned to 200 μm by mechanical abrasion using a diamond wheel. On the thinned donor substrate 100 is performed a trimming with a diamond saw to a 1.5 mm width and 220 μm depth. The remaining silicon is then etched with an aqueous solution of HF/HNO₃. Etching stops at the 400 nm silicon oxide layer. With a step of photolithography and ion etching, the 400 nm oxide is etched to open up the cutting paths. The lithography resin is then removed, and plasma etching using the Bosch method enables the chips to be singularized by etching the 50 μm of silicon. Plasma etching stops within the oxide layer of the damascene structures. Ion etching using a CHF₃ plasma with 20% CH₄ at 10 torr and 1500 W is used to etch this oxide, stopping on the silicon of handle 200. 50 μm silicon chips bonded to handle 200 are obtained.

This structure is attached to a solid frame using Furukawa SP5207M-425 adhesive tape. The thinned face of the donor substrate 100 is bonded to the tape. By inserting a wedge into the bonding, the handle 200 is disassembled. 6×6 mm² silicon chips with a thickness of 50 μm are obtained which are compatible with a hybrid hydrophilic direct bonding method after ozone cleaning and Megpie using a solution of EKC PCMP 5650 diluted 1:20 in DI water.

### Example 6

On a silicon wafer (donor substrate 100), 2 μm copper pads are performed in a SiO₂ matrix by a damascene method. This wafer undergoes a trimming with a diamond saw to a width of 1.5 mm and a depth of 220 μm. Then a cleaning and a mechanical and chemical polishing is performed so as to make it compatible with a hydrophilic direct bonding method. Immediately prior to bonding, a 30 nm-thick deposit of amorphous carbon is then performed.

On a temporary substrate 200, 1 μm of SiO₂ is formed by chemical vapor deposition. The substrate is mechanically and chemically polished. Just before bonding, a 30 nm-thick deposit of amorphous carbon is performed.

Substrates 100, 200 are assembled by direct bonding. The donor substrate 100 is thinned up to a thickness of 200 μm by mechanical abrasion. On the donor substrate 100, 3×3 mm² chips are cut with a diamond saw. The depth of the cut is 210 μm so as to ensure complete cutting of the donor substrate 100. The cut penetrates the temporary substrate 200 to a depth reduced to 10 μm.

This structure is attached to a solid frame using Adwill D-650 adhesive tape. The thinned face of the donor substrate 100 is bonded to the tape. By inserting a wedge into the bonding, the handle 200 is disassembled. 3×3 mm² silicon chips with a thickness of 200 μm are obtained, the surface of which is composed of copper 2-μm-side pads. The amorphous carbon layer is removed by a 120 s UV/Ozone process (at 21 mW/mm² with a low-pressure quartz mercury lamp with wavelengths of 254 nm and 185 nm), which does not disturb the hydride surface and, above all, the underlying copper. This surface is compatible with a hydrophilic direct bonding method. An ozone-based cleaning and a Megpie using a solution of EKC PCMP 5650 diluted 1:20 in DI water can be added.

### Example 7

On a 100 mm-diameter, 650 μm-thick InP wafer (donor substrate 100), an UV-Ozone and Megpie in a 2% ammonia solution is performed to make this surface suitable for direct bonding. On this surface, a 20 nm silicon nitride and a 20 nm TEOS-based silicon oxide at 300° C. are deposited, followed by a 100 nm amorphous silicon deposit. A CMP on this amorphous silicon layer makes it compatible with direct bonding. Process with a 1% HF solution allows this surface to be made hydrophobic by passivating the silicon surface with Si—H hydrogen bonds.

A silicon wafer (temporary substrate 200) with a thickness of 525 μm and a diameter of 100 mm undergoes a cleaning so as to make it compatible with a direct bonding method and HF process to make it hydrophobic.

The substrates 100, 200 are assembled by direct hydrophobic bonding. This assembly is annealed for 2 hours at 100° C. The 100-200 μm donor substrate is then thinned by mechanical abrasion using a diamond wheel. A 400 nm TEOS oxide is then deposited. After a step of photolithography and ion etching, the 400 nm oxide is etched to open the cutting paths. The lithography resin is then removed, and plasma etching allows chips to be singularized by etching the 200 μm InP. Plasma etching stops in the oxide layer of the donor substrate 100. This oxide layer and the amorphous silicon layer of the donor substrate 100 are then etched with standard suitable plasmas. 200 μm InP chips bonded to the handle 200 are obtained.

This structure is attached to a solid frame using Furukawa SP5207M-425 adhesive tape. The thinned face of the donor substrate 100 is bonded to the tape. By inserting a wedge into the bonding, the handle 200 is dismantled. 3×3 mm² InP chips with a thickness of 200 um are obtained. Using a silicon deep-etching machine compatible with metal frames, the silicon is etched into the surface of the chips. After UV/Ozone process and Megpie with a 1% ammonia solution, the chip surface is made compatible with a hydrophilic direct bonding method.

1. A method for bonding chips to a receiver substrate comprising the following steps:
a) providing a donor substrate in which chips are formed, the donor substrate comprising a first surface on front face and a second surface on back face
b) mounting the first surface of the donor substrate to a temporary substrate, by direct bonding,
c) preferably thinning the donor substrate from the second surface,
d) bonding the assembly consisting of donor substrate and temporary substrate on a handling device comprising a solid frame and an adhesive film, the second surface of the donor substrate being bonded to the adhesive film, the adhesion between the donor substrate and the adhesive film being greater than the adhesion between the temporary substrate and the donor substrate,
e) separating the temporary substrate from the donor substrate by dismantling the interface between the temporary substrate and the donor substrate, whereby the first front surface is directly compatible with direct bonding,
f) cutting the donor substrate so as to singularize the chips,
g) bonding the chips to the receiver substrate by direct bonding.

2. The method according to claim 1, wherein step f) is performed between step b) and step d).

3. The method according to claim 1, wherein, in step b), the first surface of the donor substrate is coated by a protective layer.

4. The method according to claim 3, wherein the protective layer is an amorphous carbon layer, a silicon layer or a polymer layer, for example a layer of acrylate or one of its derivatives.

5. The method according to claim 1, wherein the first surface of the donor substrate is a surface comprising silicon oxide and copper.

6. The method according to claim 1, wherein the first surface of the donor substrate is a surface of silicon, germanium, a III/V material, such as AsGa, InP or a II/VI material, such as CdHgTe.

7. The method according to claim 1, wherein a step of trimming the donor substrate is performed before step b) or after step b).

8. The method according to claim 1, wherein the chips have a surface area of between 0.5×0.5 mm² and 20×20 mm².

9. The method according to claim 1, wherein the chips have a thickness of less than 300 μm, preferably less than 100 μm, even more preferably less than 50 μm.

10. The method according to claim 1, wherein step f) is performed by plasma etching.

11. The method according to claim 1, wherein step e) is performed by inserting a wedge or blade between the temporary substrate and the donor substrate.
